(19) United States
(12) Patent Application Publication
(10) Pub. No.: US 2013/0169591 A1
(43) Pub. Date: Jul. 4, 2013

(54) STRENGTHENED GLASS BLOCK, TOUCH-SENSITIVE DISPLAY DEVICE AND OLED DISPLAY DEVICE

(71) Applicant: WINTEK CORPORARTION, Taichung City (TW)

(72) Inventors: Jeng-Jye HUNG, TAI PING CITY (TW); Hen-Ta KANG, TAI CHUNG CITY (TW); Chien-Chung CHEN, TAI CHUNG CITY (TW)

(73) Assignee: WINTEK CORPORARTION, Taichung City (TW)

(21) Appl. No.: 13/732,795

(22) Filed: Jan. 2, 2013

(30) Foreign Application Priority Data
Jan. 4, 2012 (TW) 101100346

(51) Int. Cl. C03C 21/00; G06F 3/044

(52) U.S. Cl. CPC C03C 21/00; G06F 3/044
USPC 345/174; 428/192; 428/156; 428/157; 428/172; 65/30.14

(57) ABSTRACT

A strengthened glass block cut from a mother glass substrate is provided. The mother glass substrate is given a preliminary chemically strengthening treatment, the strengthened glass block has a preliminary strengthened surface area and a newly-born surface area, and the newly-born surface area is formed as a result of a machining or material removing treatment. A chemically strengthened layer formed as a result of a secondary chemically strengthening treatment is formed in at least the newly-born surface area.

### BACKGROUND OF THE INVENTION

a. Field of the Invention

The invention relates to a strengthened glass block and to a touch-sensitive display device and an OLED display device having the strengthened glass block.

b. Description of the Related Art

Generally, conventional methods for strengthening glass mainly include a physically strengthening treatment and a chemically strengthening treatment. For example, in a typical chemically strengthening treatment an ion-exchange phenomenon occurs in the glass skin to form a chemically strengthened layer. Under the circumstance, a compression stress layer is correspondingly formed on the glass skin as a result of the chemically strengthened layer and capable of constraining the growth of cracks on the glass skin to enhance the glass strength. Currently, typical processes for using chemically strengthened glass in the fabrication of an electronic product are described below. First, a mother glass substrate is cut to form multiple glass blocks each having a size and a shape corresponding to a finished product. Then, each glass block is given a chemically strengthening treatment and other necessary fabrication processes. In other words, each of the glass blocks cut from a mother glass substrate needs to be chemically strengthened one after one to thus complicate fabrication processes and increase fabrication time and costs.

Accordingly, in case a mother glass substrate is given a chemically strengthening treatment and undergoes necessary fabrication processes in advance before being cut, multiple glass blocks each having a stack of films and serving as a final product are directly formed immediately after cutting the mother glass substrate. Such fabrication process is typically referred to as a “mother glass fabrication process” that allows to simplify fabrication processes and reduce processing time. However, in the mother glass fabrication process, in case a machining or material removing treatment is given on a mother glass substrate having been given a preliminary chemically strengthening treatment, a newly-born surface area without a chemically strengthened layer is formed to reduce the glass strength.

### BRIEF SUMMARY OF THE INVENTION

The invention provides a strengthened glass block entirely covered with a strengthen layer to achieve great strength.

Other objects and advantages of the invention can be better understood from the technical characteristics disclosed by the invention. In order to achieve one of the above purposes, all the purposes, or other purposes, one embodiment of the invention provides a strengthened glass block cut from a mother glass substrate. The mother glass substrate is given a preliminary chemically strengthening treatment, the strengthened glass block has a preliminary strengthened surface area and a newly-born surface area, and the newly-born surface area is formed as a result of a machining or material removing treatment. A chemically strengthened layer formed as a result of a secondary chemically strengthening treatment is formed in at least the newly-born surface area.

According to another embodiments of the invention, a strengthened glass block cut from a mother glass substrate is provided. The mother glass substrate is given a preliminary chemically strengthening treatment, a machining or material removing treatment, and a secondary chemically strengthening treatment in succession. The strengthened glass block has a preliminary strengthened surface area and a newly-born surface area, the newly-born surface area is formed as a result of the machining or material removing treatment, and the strengthened glass block satisfies the following condition:

(d/T)≦70%,

where d is an average depth of a strengthened layer existing in the newly-born surface area and T is an average depth of a strengthened layer existing in the preliminary strengthened surface area.

According to another embodiments of the invention, a touch-sensitive display device protected by strengthened glass includes a cover lens and a display device. The cover lens is cut from a mother glass substrate given a preliminary chemically strengthening treatment. The cover lens has a preliminary strengthened surface area and a newly-born surface area, and the newly-born surface area is formed as a result of a machining or material removing treatment. A chemically strengthened layer formed as a result of a secondary chemically strengthening treatment is formed in at least the newly-born surface area. A display device with touch-sensing functions is disposed on the cover lens.

According to another embodiments of the invention, an OLED display device includes a cover lens, a touch-sensing structure and a substrate. The cover lens is cut from a mother glass substrate given a preliminary chemically strengthening treatment. The cover lens has a preliminary strengthened surface area and a newly-born surface area, and the newly-born surface area is formed as a result of a machining or material removing treatment. A chemically strengthened layer formed as a result of a secondary chemically strengthening treatment is formed in at least the newly-born surface area. The touch-sensing structure is disposed on the cover lens, and the substrate is disposed adjacent to the cover lens and has an OLED unit.

According to the above embodiments, a chemically strengthened layer formed as a result of a secondary chemically strengthening treatment may be given to cover the newly-born surface area or to reinforce the original strengthened layer that is weaken or removed in part as a result of the machining or material removing treatment. Therefore, a chemically strengthened layer and a compression stress layer formed as a result of the chemically strengthened layer are provided on the entire strengthened glass block to enhance the overall strength of the strengthened glass block. Under the circumstance, a product may be produced by a mother glass fabrication process with simplified procedures and reduced fabrication time and costs.

Other objectives, features and advantages of the invention will be further understood from the further technological features disclosed by the embodiments of the invention wherein there are shown and described preferred embodiments of this invention, simply by way of illustration of modes best suited to carry out the invention.

### BRIEF DESCRIPTION OF THE DRAWINGS

FIG. 1 shows a schematic diagram illustrating chemically strengthened mother glass substrate according to an embodiment of the invention.

FIG. 2 shows a schematic diagram illustrating a machining or material removing treatment and a secondary chemically strengthening treatment on a glass substrate according to an embodiment of the invention.

FIG. 3 shows a schematic diagram illustrating a machining or material removing treatment and a secondary chemically strengthening treatment on a glass substrate according to another embodiment of the invention.

FIG. 4 shows a schematic diagram illustrating a machining or material removing treatment and a secondary chemically strengthening treatment on a glass substrate according to another embodiment of the invention.

FIG. 5 shows a schematic diagram illustrating a machining or material removing treatment and a secondary chemically strengthening treatment on a glass substrate according to another embodiment of the invention.

FIG. 6A and FIG. 6B are schematic diagrams illustrating changes in the depth of a chemically strengthened layer on a chemically strengthened glass substrate.

FIG. 6C shows a partial cross-section of a cover lens for illustrating changes in the depth of a chemically strengthened layer.

FIG. 7 shows a partial enlarged cross-section of a cut glass substrate.

FIG. 8 shows a schematic cross-section of a cover lens in combination with a touch-sensing structure and a display device according to an embodiment of the invention.

FIG. 9 shows a schematic plan view of a cover lens in combination with a touch-sensing structure shown in FIG. 8 according to an embodiment of the invention.

FIG. 10 shows a schematic plan view of a cover lens in combination with a touch-sensing structure shown in FIG. 8 according to another embodiment of the invention.

FIG. 11 shows a schematic cross-section of a cover lens having a curved side surface in combination with a touch panel and a display device according to an embodiment of the invention.

FIG. 12 shows a schematic cross-section of a touch-sensitive display device according to an embodiment of the invention.

FIG. 13 shows a schematic cross-section of a touch-sensitive display device according to another embodiment of the invention.

FIG. 14 shows a cross-section of a touch-sensitive display device according to another embodiment of the invention.

FIG. 15 shows a cross-section of a touch-sensitive display device according to another embodiment of the invention.

### DETAILED DESCRIPTION OF THE INVENTION

In the following detailed description of the preferred embodiments, reference is made to the accompanying drawings which form a part hereof, and in which are shown by way of illustration specific embodiments in which the invention may be practiced. In this regard, directional terminology, such as “top,” “bottom,” “front,” “back,” etc., is used with reference to the orientation of the Figure(s) being described. The components of the invention can be positioned in a number of different orientations. As such, the directional terminology is used for purposes of illustration and is in no way limiting. On the other hand, the drawings are only schematic and the sizes of components may be exaggerated for clarity. It is to be understood that other embodiments may be utilized and structural changes may be made without departing from the scope of the invention. Also, it is to be understood that the phraseology and terminology used herein are for the purpose of description and should not be regarded as limiting. The use of “including,” “comprising,” or “having” and variations thereof herein is meant to encompass the items listed thereafter and equivalents thereof as well as additional items. Unless limited otherwise, the terms “connected,” “coupled,” and “mounted” and variations thereof herein are used broadly and encompass direct and indirect connections, couplings, and mountings. Similarly, the terms “facing,” “faces” and variations thereof herein are used broadly and encompass direct and indirect facing, and “adjacent to” and variations thereof herein are used broadly and encompass directly and indirectly “adjacent to”. Therefore, the description of “A” component facing “B” component herein may contain the situations that “A” component directly faces “B” component or one or more additional components are between “A” component and “B” component. Also, the description of “A” component “adjacent to” “B” component herein may contain the situations that “A” component is directly “adjacent to” “B” component or one or more additional components are between “A” component and “B” component. Accordingly, the drawings and descriptions will be regarded as illustrative in nature and not as restrictive.

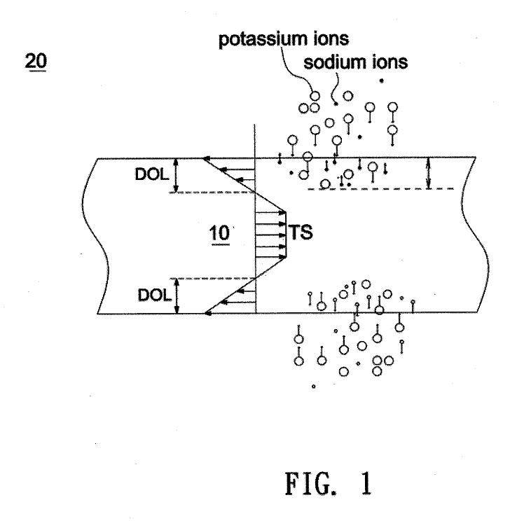

As shown in FIG. 1, according to an embodiment of the invention, a mother glass substrate 10 is first given a preliminary chemically strengthening treatment to form a strengthened mother glass substrate 20. For example, the chemically strengthening treatment may be an ion-exchange strengthening treatment. In a typical ion-exchange strengthening treatment, the mother glass substrate 10 to be strengthened is submersed in a bath containing a potassium salt. This causes sodium ions on the glass surface to be replaced by potassium ions from the bath solution to form a chemically strengthened layer. Under the circumstance, a compression stress layer DOL is formed on the skin of a mother glass substrate 10, and a tensile stress is correspondingly formed inside the mother glass substrate 10 to compensate the compression stress of the compression stress layer DOL. A thicker compression stress layer DOL may enhance the capability of constraining the growth of cracks to much more strengthen the mother glass substrate 10 and increase the resistance to an impact of a foreign body. In one embodiment, a depth of a chemically strengthened layer is defined as an average depth measured from the skin of a glass substrate to an inner position where potassium ions farthest reach. Preferably, a depth of a chemically strengthened layer is defined as an average value of maximum diffusion depths of potassium ions. A diffusion depth can be detected by an instrument and determined according to the existence of potassium ions. Since diffusion depths are provided with varying levels even under an identical fabrication process, the term “diffusion depth of a chemically strengthened layer” is defined as an average of different measured values of diffusion depths. For instance, Varshneya (1975) discovered that, in his research, a depth of a chemically strengthened layer is slight larger than a depth of a compression stress layer DOL. In a mother glass fabrication process, in case a machining or material removing treatment is given on a strengthened mother glass substrate 20 having been given a preliminary chemically strengthening treatment, a newly-born surface area without a strengthened layer is formed on the strengthened mother glass substrate 20. Since the newly-born surface area is not protected by a strengthened layer, surface cracks are liable to grow to reduce the strength of the strengthened mother glass substrate 20. In that case, an additional strengthened layer formed as a result of a secondary chemically strengthening treatment may be given to strengthen the newly-born surface area or to reinforce the original strengthened layer that is weaken or removed in part as a result of the machining or material removing treatment. This may provide the strengthened mother glass substrate 20 with great strength.

The process of a secondary chemically strengthening treatment is exemplified in the following embodiments, where the secondary chemically strengthening treatment is performed on a strengthened mother glass substrate that has been given a preliminary chemically strengthening treatment and then given a machining or material removing treatment.

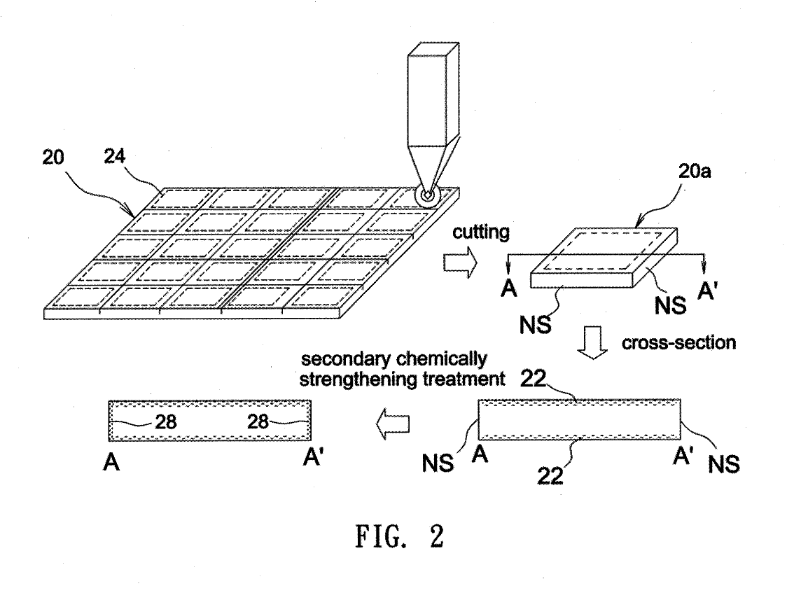

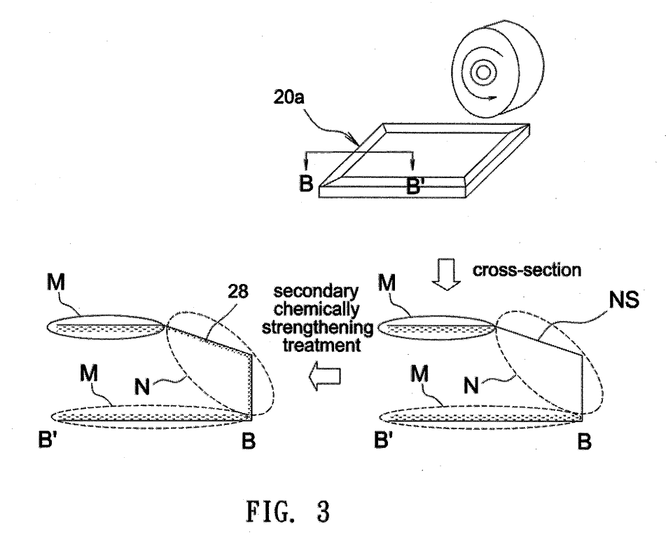

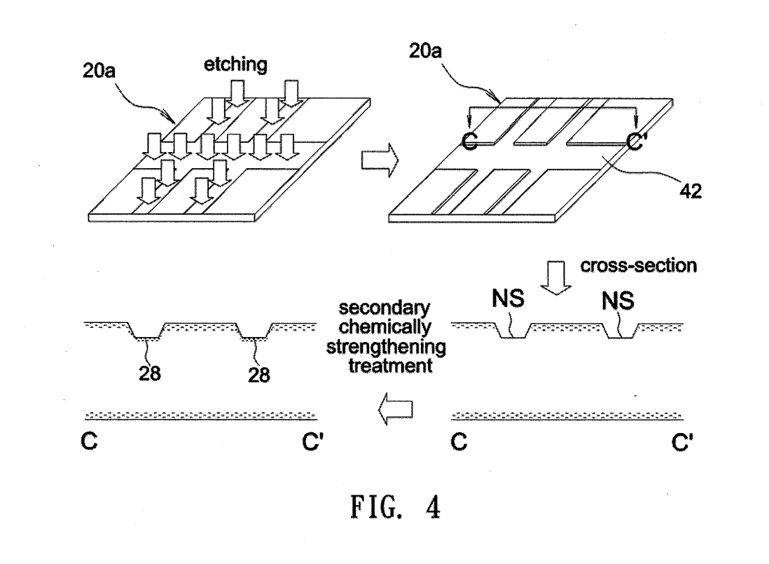

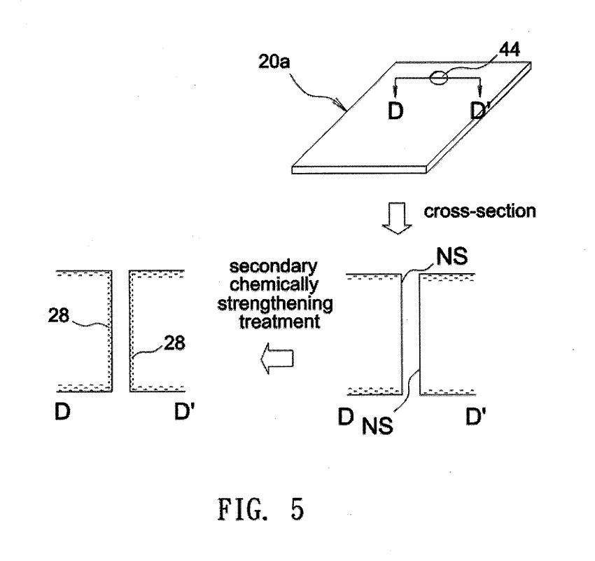

As shown in FIG. 2, a mother glass fabrication process is performed on a strengthened mother glass substrate 20 having been given a preliminary chemically strengthening treatment. Herein, the mother glass fabrication process means necessary processes for producing a finished product and performed on a mother glass substrate. For example, in case a strengthened glass substrate serves as a substrate or a cover lens of a touch panel, the mother glass fabrication process may include a first photolithography process for forming metal traces, a second photolithography process for forming an insulation layer, a third photolithography process for forming multiple first sensing series and second sensing series, and forming a decorative layer by a photolithography, screen printing or ink printing process. In that case, multiple touch-sensing structures 24 to be separated are formed on the strengthened mother glass substrate 20. The material of the decorative layer includes at least one of diamond-like carbon, ceramic, colored ink, resin and photo resist. Also, the decorative layer may be formed on a touch panel, a display panel, or a cover lens or a glass substrate of other electronic product. Alternatively, in case the strengthened glass substrate serves as a transparent substrate of a display panel, the mother glass fabrication process may include depositing metal and dielectric materials and performing photolithography and etching processes on a strengthened mother glass substrate 20 to form a display unit. The display unit may include, for example, an LED unit or an OLED unit. After the mother glass fabrication process has been carried out, the strengthened mother glass substrate 20 is cut to directly form multiple strengthened glass blocks 20a each having a stack of films. Therefore, a product may be produced by the mother glass fabrication process with simplified procedures and reduced fabrication time and costs. Further, since the aforementioned cutting treatment allows each strengthened glass block 20a to form four newly-born surfaces NS (i.e., four cut facets), and each of the newly-born surfaces NS is not provided with a chemically strengthened layer 22, the strengthened glass block 20a is then given a secondary chemically strengthening treatment to form a chemically strengthened layer 28 and correspondingly form a compression stress layer on the newly-born surface NS. Therefore, a chemically strengthened layer and a compression stress layer formed as a result of the chemically strengthened layer are provided on the entire strengthened glass block 20a to enhance the overall strength of the strengthened glass block 20a. As shown in FIG. 3, the strengthened glass block 20a may be edged by grinding to form a newly-born surface NS without a chemically strengthened layer or with a slight residue of a chemically strengthened layer, and, after the secondary chemically strengthening treatment is performed, a chemically strengthened layer is similarly formed on the newly-born surface NS. Therefore, according to the above embodiments, a strengthened glass block 20a cut from a mother glass substrate 20 having been given a preliminary chemically strengthening treatment is provided. The strengthened glass block 20a includes a preliminary strengthened surface area M and at least one newly-born surface area N, where the newly-born surface area N is formed as a result of a machining or material removing treatment. Further, a chemically strengthened layer 28 formed as a result of the secondary chemically strengthening treatment is at least formed in the newly-born surface area N. Besides, except for the newly-born surface area N, the chemically strengthened layer 28 may be optionally formed in part of the preliminary strengthened surface area M, such as being formed in a selected region of the preliminary strengthened surface area M neighboring the newly-born surface area N, to further increase the glass strength of the selected region. If necessary, the secondary chemically strengthening treatment may be given to the entire preliminary strengthened surface area M. Certainly, the machining or material removing treatment is not limited to specific processes, as long as a newly-born surface area N is formed. For example, the strengthened glass block 20a may be, for example, etched (a notch 42 shown in FIG. 4 is etched on the strengthened glass block 20a), drilled (a hole 44 shown in FIG. 5 and penetrating or not penetrating the strengthened glass block 20a), polished or rounded to form a newly-born surface NS, and the chemically strengthened layer 28 formed as a result of a secondary chemically strengthening treatment is at least given to the newly-born surface area N. Under the circumstance, a chemically strengthened layer and a corresponding compression stress layer are formed on the entire surface of the strengthened glass block 20a to enhance the overall strength. Certainly, the strengthened glass block 20a may be given multiple different machining or material removing treatments, and a secondary chemically strengthening treatment is performed on the finally shaped newly-born surface. For example, the strengthened glass block 20a is first given machining treatments such as cutting, edging and chamfering operations, and peripheral cracks formed as a result of the machining treatments are removed by etching using an etching agent such as hydrofluoric acid to increase the bending strength of the machined glass block 20a to eliminate or reduce the formation of cracks that are the source of splitting glass. Then, a secondary chemically strengthening treatment is provided to allow for a chemically strengthened layer on the entire surface of the strengthened glass block 20a.

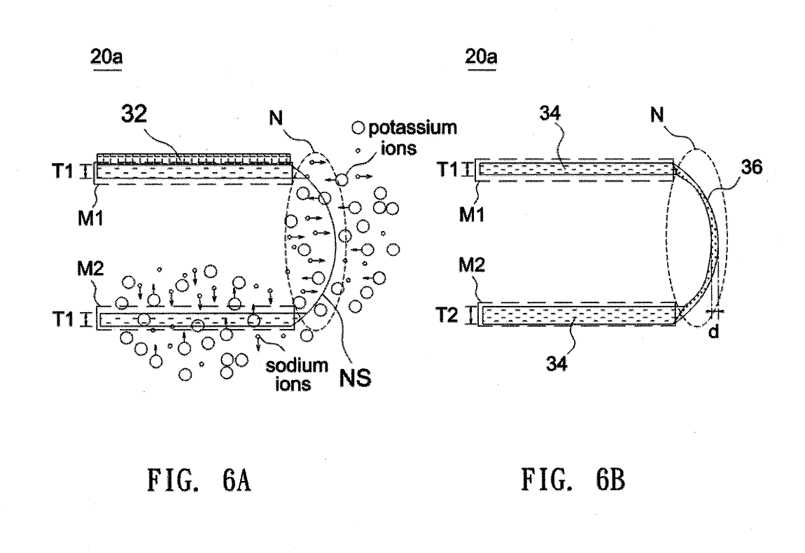

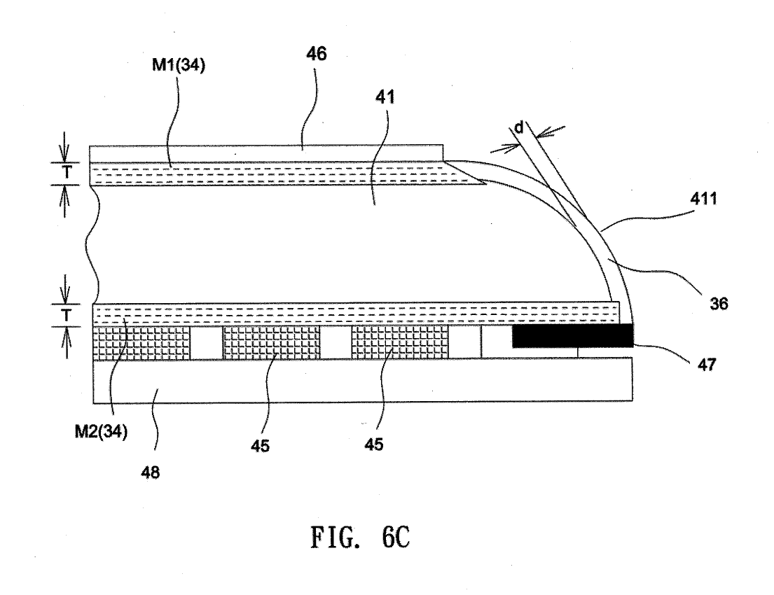

FIG. 6A and FIG. 6B are schematic diagrams illustrating changes in the depth of a chemically strengthened layer on a chemically strengthened glass substrate. FIG. 6A shows a strengthened glass block 20a cut from a mother glass substrate given a preliminary chemically strengthening treatment, and the strengthened glass block 20a is rounded to form a newly-born surface NS. FIG. 6B shows a schematic diagram illustrating the strengthened glass block 20a having been given a secondary chemically strengthening treatment. As shown in FIG. 6A, since the mother glass substrate is given a preliminary chemically strengthening treatment, the strengthened glass block 20a may have a chemically strengthened layer with a depth T1, and the newly-born surface NS formed as a result of rounding does not have a chemically strengthened layer or may have a weakened chemically strengthened layer. When the secondary chemically strengthening treatment is performed, regions M1 and M2 already having a chemically strengthened layer with a depth T1 may be or may not be shaded by a shielding layer 32. The shielding layer 32 may be a sheet attached to the strengthened glass block 20a or a thin film coated on the strengthened glass block 20a. The sheet or thin film may be optionally removed after an etching treatment or a secondary chemically strengthening treatment is given. In case the shielding layer 32 remains on the strengthened glass block 20a, the shielding layer 32 may function as at least one of an anti-reflection film, an anti-glare film or an anti-scratch film according to the selection of different materials and thicknesses. Further, when the secondary chemically strengthening treatment is performed, potassium ions may diffuse into the shielding layer 32 (such as a thin film) and alter the index of refraction of the thin film to allow the index of refraction to reach a preset value. The thin film that has a specific index of refraction and functionalities may cooperate with a strengthened glass substrate to enhance light-transmittance of the strengthened glass substrate and reduce reflectivity of ambient light incident to the strengthened glass substrate. When a secondary chemically strengthening treatment is provided, a chemically strengthened layer with a depth d may be formed on the newly-born surface area N, the chemically strengthened layer in the preliminary strengthened surface area M1 shaded by the shielding layer 32 maintain a depth T1, and the chemically strengthened layer in the preliminary strengthened surface area M2 not shaded by the shielding layer 32 has a depth T2 deeper than depth T1 (T2>T1). Therefore, in case the chemically strengthened layer in the preliminary strengthened surface area M2 formed as a result of a preliminary chemically strengthening treatment is weakened or partially removed as a result of a machining or material removing treatment, a secondary chemically strengthening treatment may remedy such deficiencies. Under the circumstance, in one embodiment, preliminary strengthened surface areas M1 and M2 may larger than the newly-born surface area N, a chemically strengthened layer formed as a result of a preliminary chemically strengthening treatment may exist only in the preliminary strengthened surface areas M1 and M2, and a chemically strengthened layer formed as a result of a secondary chemically strengthening treatment may exist in the preliminary strengthened surface area M2 and not exist in the preliminary strengthened surface area M1. In other words, the secondary chemically strengthening treatment may reinforce a selected region of the preliminary strengthened surface area. Besides, a chemically strengthened layer formed as a result of a secondary chemically strengthening treatment may be formed in part of the preliminary strengthened surface area M1. For example, a part of the preliminary strengthened surface area M1 neighboring a rounded region (newly-born surface area N) may be not shaded by the shielding layer 32 to receive the secondary chemically strengthening treatment.

In an alternate embodiment, as shown in FIG. 6C, the strengthened glass block 20a may serve as a cover lens 41, and a touch-sensing structure 45 and a decorative layer 47 are formed in the preliminary strengthened surface area M2 through fabrication processes such as photolithography and screen printing. Then, when a secondary chemically strengthening treatment is performed, shielding layers 46 and 48 respectively shade the preliminary strengthened surface areas M1 and M2 to allow the chemically strengthened layer in the preliminary strengthened surface areas M1 and M2 to keep a constant depth, avoid ion-exchange or diffusion behaviors, and prevent the strengthened glass block 20a from deforming. In this embodiment, at least one cut facet of the strengthened glass block 20a is given a machining or material removing treatment first to form a curved surface 411 and then given post treatments such as etching, polishing or a secondary chemically strengthening treatment, and finally the shielding layers 46 and 48 may be optionally removed. For example, the shielding layer 46 (such as a coated thin film) is reserved for providing specific optical functions, and the shielding layer 48 (such as an attached protective sheet) is removed. Certainly, the shielding layer 46 may be also removed.

In other words, according to the above embodiment, the skin of a strengthened glass block 20a may be spread with at least a first strengthened layer 34 and a second strengthened layer 36, the first strengthened layer 34 (may exist in the preliminary strengthened surface areas M1 and M2) may be formed as a result of a preliminary chemically strengthening treatment and a secondary chemically strengthening treatment, and a second strengthened layer 36 (may exist in a newly-born surface area N) may be formed as a result of only a secondary chemically strengthening treatment. The first strengthened layer 34 has a depth T (T=T1 or T2), and the second strengthened layer 36 has a depth d. For example, when a thin film structure (such as a touch-sensing structure or a display unit) is already formed on a glass substrate before a secondary chemically strengthening treatment is given, the processing temperature and time needed by the secondary chemically strengthening treatment are smaller than the processing temperature and time needed by a preliminary chemically strengthening treatment to avoid damage to the thin film structure. Therefore, a depth of the strengthened layer formed as a result of a secondary chemically strengthening treatment may smaller than a depth of the strengthened layer formed as a result of a preliminary chemically strengthening treatment. Under the circumstance, a strengthened glass block 20a given a preliminary chemically strengthening treatment, a machining or material removing treatment and a secondary chemically strengthening treatment may satisfy the following condition:

(d/T)≦70%,

where d is an average depth of a strengthened layer existing in the newly-born surface area N, and T is an average depth of a strengthened layer existing in the preliminary strengthened surface areas M1 and M2.

In one embodiment, a depth of each of the strengthened layers 34 and 36 may be defined as an average diffusion depth of potassium ions that diffuse from the skin to the inside of a glass substrate, and the average diffusion depth is determined according to multiple measurement points. Typically, a distribution density of potassium ions is highest on the skin and gradually decreased to zero or a background value towards the inside of the glass substrate. Hence, a depth measured at each measurement point is substantially equal to a distance between the skin and a position inside the glass substrate where a distribution density of potassium ions is decreased to zero or a background value. The background value may be detected as a result of the composition of a glass material. For example, a glass material may inherently contain potassium ions. More specifically, since a chemically strengthened layer is formed as a result of ion exchange or diffusion and a distribution density of ions (such as potassium ions) is highest on the skin and gradually decreased to zero or a background value towards the inside of the glass substrate, the chemically strengthened layer can be recognized by detecting the existence of exchanged ions. Herein, an average diffusion depth may be an average depth of a strengthened layer and, preferably, may be an average maximum diffusion depth of potassium ions that diffuse to the inside of a glass substrate. Actually, even in an identical chemically strengthening process, depths of chemically strengthened layer measures at two neighboring points may be slightly different from each other. Therefore, sampling different depths at different positions of a chemically strengthened layer is needed, and then the sampled values are averaged out. For example, an instrument is used to sample diffusion paths of potassium ions at five measurement points of a strengthened glass substrate and then average out the five sampled values, and the average value indicates an average depth (T or d) of the overall chemically strengthened layer. Further, the ion-exchange treatment is not limited to the exchange between potassium ions and sodium ions exemplified above, and any ion-exchange behavior capable of enhancing glass strength is suitable for all the above embodiments. Besides, the material of a glass substrate includes, but is not limited to, sodium calcium silicate glass and aluminosilicate glass.

According to the above embodiments, a glass strengthening method may include the following steps. First, after a preliminary chemically strengthening treatment is given to a mother glass substrate, a mother glass substrate process is performed on the mother glass substrate. The mother glass substrate process may include at least one of film deposition, photolithography, etching, screen printing and ink printing to form at least one of a touch-sensing structure and a display unit. Then, the mother glass substrate is cut to form multiple strengthened glass blocks, and each strengthened glass block is given a machining or material removing treatment and a secondary chemically strengthening treatment. The machining or material removing treatment includes at least one of edging, drilling, chamfering, etching and polishing operations, and an etching agent may be used to etch a periphery of each strengthened glass block to eliminate peripheral cracks formed as a result of the machining or material removing treatment.

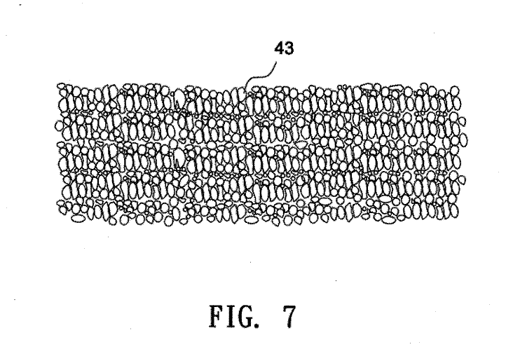

As described above, in a period between a preliminary chemically strengthening treatment and a secondary chemically strengthening treatment are performed, peripheral cracks formed on a glass substrate as a result of cutting, drilling, edging or chamfering are removed or diminished by etching, using an etching agent such as hydrofluoric acid, to reduce the possibility that the glass substrate splits via the peripheral cracks on suffering external impacts. In that case, as shown in FIG. 7, a plurality of etched notch structures 43 having an arc-shaped or a tooth-shaped profile are formed in the newly-born surface area. The etching agent may be a dry etching agent or a wet etching agent. For example, the dry etching agent may be fluorine-containing gas or plasma, and the wetting agent may be a solvent containing hydrofluoric acid or fluorine.

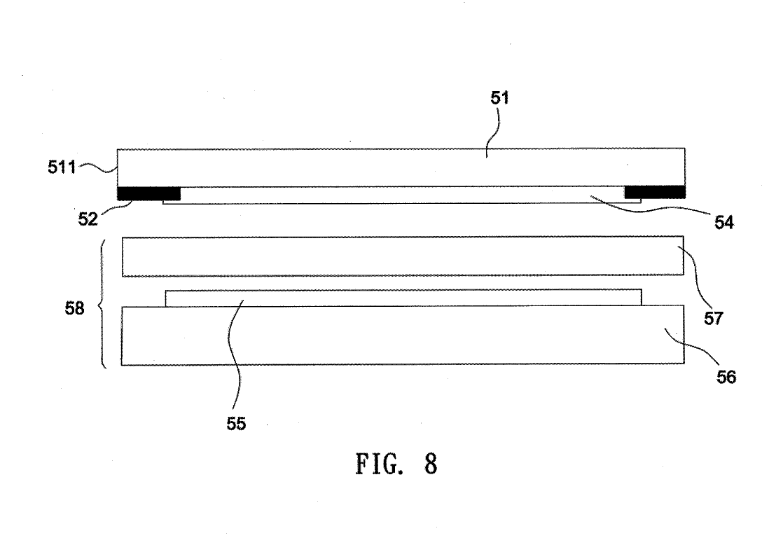

Referring to FIG. 8, in one embodiment, before cutting a mother glass substrate, the mother glass substrate may undergo a mother glass fabrication process, such as film deposition, photolithography, etching, screen printing or ink printing to form a decorative layer 52 and a touch-sensing structure 54, and then the mother glass substrate is cut to form multiple strengthened glass blocks 20a each serving as a cover lens 51. The decorative layer 52 and a touch-sensing structure 54 may be formed on the same side of the cover lens 51, and the touch-sensing structure 54 may be, for example, a capacitive-type touch-sensing structure. A side surface 511 of the cover lens 51 is optionally given an etching treatment and a secondary chemically strengthening treatment to obtain a strengthened cover lens 51. Further, display units may be formed on a mother glass substrate by aforementioned mother glass fabrication process, and the mother glass substrate is cut to form multiple strengthened glass blocks 20a each functioning as an array substrate, and the array substrate may serve as a bottom substrate 56 of an LCD device or an OLED device and combines with a color filter substrate or a sealing cap 57 to form a display device 58.

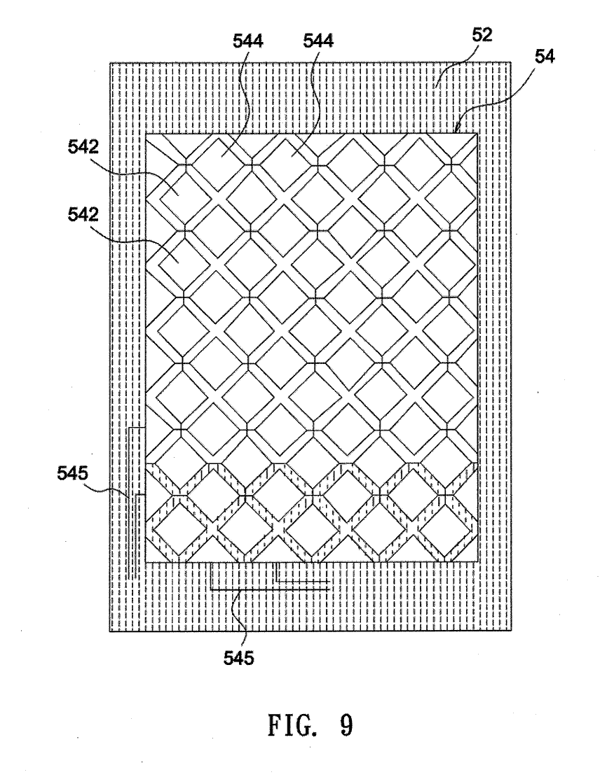

Typically, a touch-sensing structure is formed by patterning an electrode layer. For example, as shown in FIG. 9, a touch-sensing structure 54 mainly includes multiple vertically extending first sensing series 542 and horizontally extending second sensing series 544. Conductive traces 545 are formed on the decorative layer 52 or serve as connection wires inside the sensing series. The conductive traces 545 may be metallic or transparent. Note only a part of the conductive traces 545 is depicted in FIG. 9, and other parts of the conductive traces 545 are omitted.

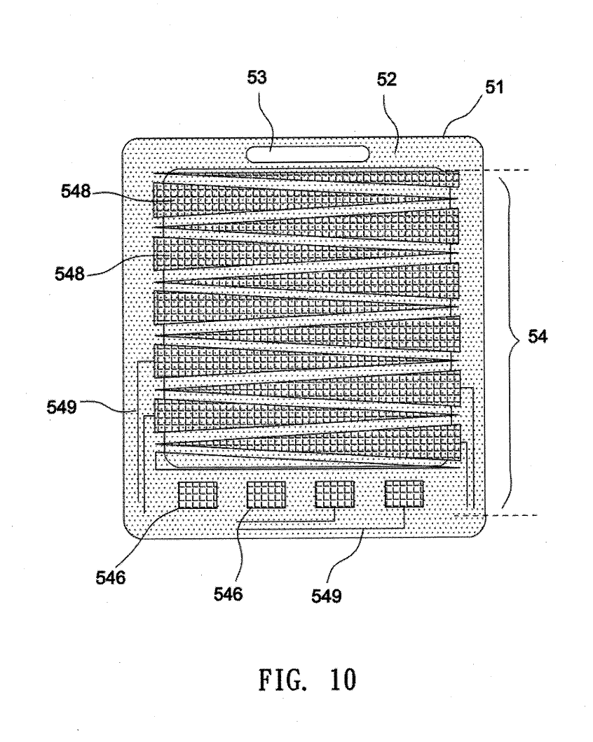

Further, the touch-sensing structure 54 may be formed by patterning a single-layered electrode layer. For example, as shown in FIG. 10, the touch-sensing structure 54 mainly includes button-type single-layered electrodes 546 and triangle-type single-layered electrodes 548. The button-type single-layered electrodes 546 or the triangle-type single-layered electrodes 548 may form a transparent electrode pattern occupying an entire plane or form a mesh-wire pattern shown in FIG. 10. Conductive traces 549 are formed on the decorative layer 52, and the conductive traces 545 may be metallic or transparent. Note only a part of the conductive traces 549 is illustrated in FIG. 10, and the other parts of the conductive traces 545 are omitted. At least one hole 53 is formed on the decorative layer 52 above the cover lens 51. After the etching and secondary chemically strengthening treatments are performed, the strength of a side wall defining the hole 53 is effective increased.

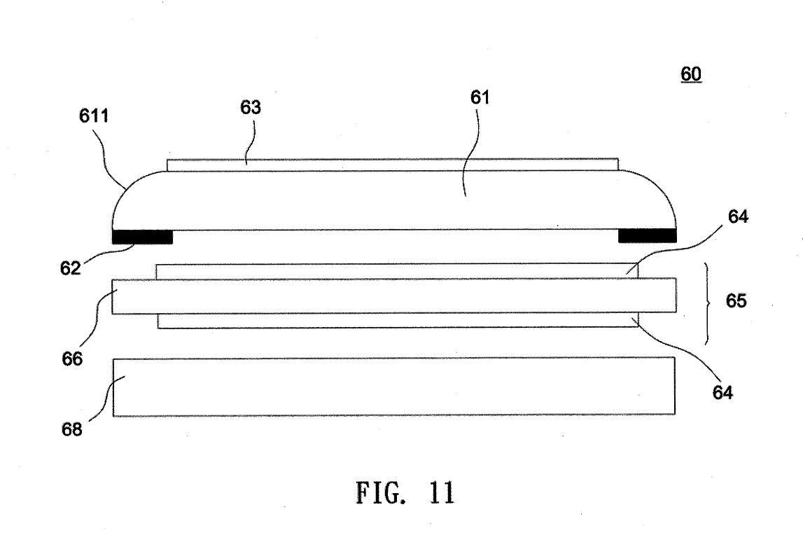

Please refer to FIG. 6A, FIG. 6B and FIG. 11, in case the strengthened glass block 20a functions as a cover lens, a secondary chemically strengthening treatment may be given to the strengthened glass block 20a having been given machining treatments. In this embodiment, at least one side of the cover lens 61 is machined (such as edged and chamfered) to form a curved surface 611, and then the curved surface 611 is given a secondary chemically strengthening treatment. Before the secondary chemically strengthening treatment starts, a shielding layer is disposed on the cover lens 61 in advance by, for example, coating an optical film 63 on the cover lens 61. After the secondary chemically strengthening treatment completes, the optical film 63 is reserved for specific functionality. For example, the optical film 63 may function as an anti-reflection film, an anti-glare film or an anti-scratch film according to the selection of different materials and thicknesses. A decorative layer 62 is formed on another surface of the cover lens 61, and a shielding layer, such as a removable protective film, is attached to the surface where the decorative layer 62 is disposed before the secondary chemically strengthening treatment starts. The protective film is torn out after the secondary chemically strengthening treatment completes. In this embodiment, a finished cover lens 61, a touch panel 65 and a display device 68 together form a touch-sensitive display device 60, where the touch panel 65 includes a substrate 66 and a touch-sensing structure 64. The display device 68 may be a flat panel display, and the touch panel 65 may be disposed between the cover lens 61 and the display device 68. Though, in this embodiment, the touch-sensing structure 64 is formed on two opposite sides of the substrate 66, this is not limited. In an alternate embodiment, the touch-sensing structure 64 may be formed on only one side of the substrate 66. The substrate 66 may be a plastic thin film or a glass substrate, and the glass substrate may be, but not limited to, an ultra-thin glass substrate having a thickness of 0.1-0.2 mm.

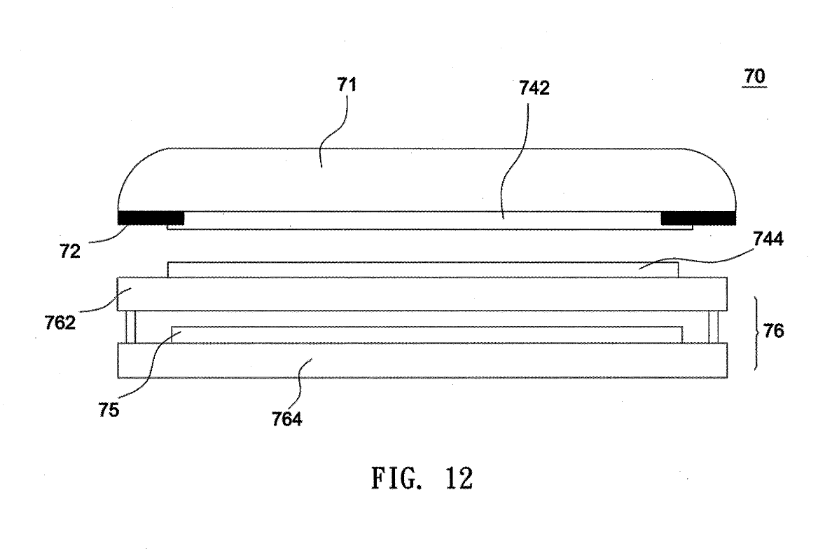

Referring to FIG. 12, in one embodiment, before cutting a mother glass substrate, the mother glass substrate may undergo a mother glass fabrication process, such as film deposition, photolithography, etching, screen printing or ink printing to form a decorative layer 72 and a touch-sensing structure 742, and then the mother glass substrate is cut to form multiple small pieces each serving as a cover lens 71. In contrast to aforementioned embodiments, a touch-sensing structure 744 according to this embodiment is directly disposed on a color filter substrate 762 of a display device 76, and the touch-sensing structures 742 and 744 together form a touch-sensing element. The touch-sensing structures 742 and 744 may be patterned electrode layers. The display device 76 may further include a bottom substrate 764 and a display unit disposed on the bottom substrate 764. The bottom substrate 764 and the color filter substrate 762 together form the display device 76.

In an alternate embodiment, the touch-sensing structure 744 may be omitted and only the touch-sensing structure 742 performs touch-sensing operations to form a display device 76 with touch-sensing functions, and the touch-sensing structure 742 may include single-layer electrodes or multi-layered electrodes. Besides, in this embodiment, the color filter substrate 762 is replaced with a sealing cap of an OLED. The cover lens 71 is combined with the display device 76 with touch-sensing functions to form a touch-sensitive display device 70 protected by strengthened glass.

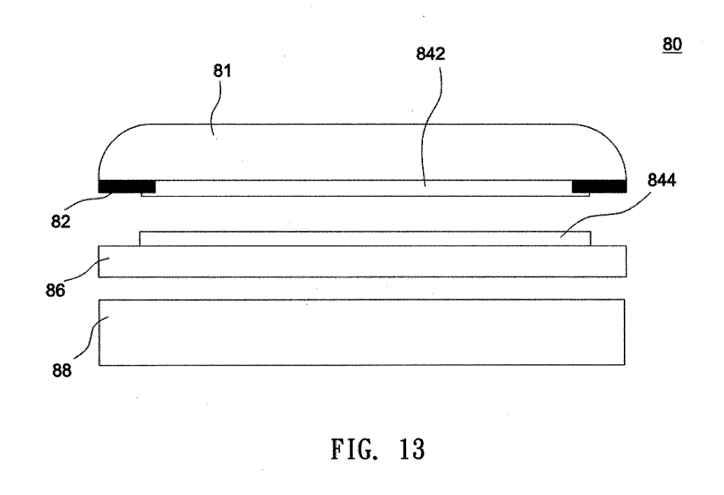

As shown in FIG. 13, contrast to the above embodiment, touch-sensing structures 842 and 844 in this embodiment are respectively disposed on a cover lens 81 of a touch-sensitive display device 80 and a transparent substrate 86. In that case, the cover lens 81 is combined with the transparent substrate 86 and a display device 88 to form a touch-sensitive display device 80 protected by strengthened glass.

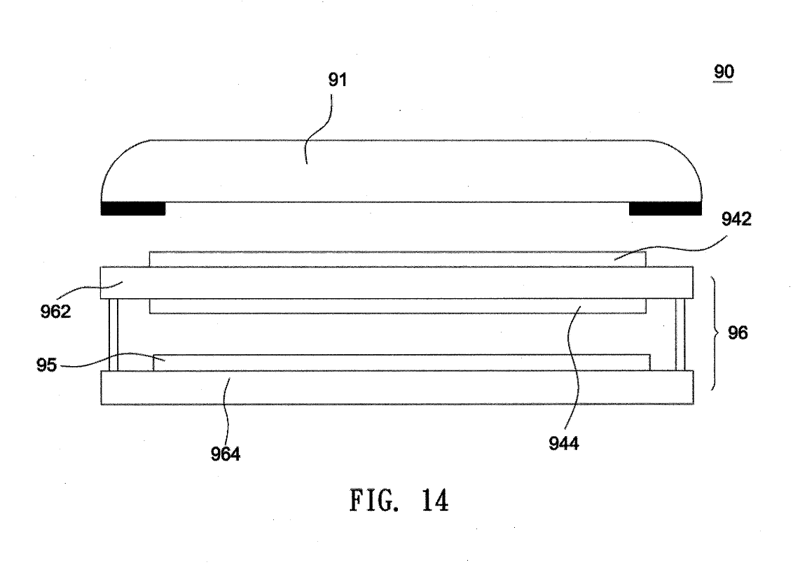

FIG. 14 shows a cross-section of a touch-sensitive display device 90 according to another embodiment of the invention. Referring to FIG. 14, in this embodiment, touch-sensing structures 942 and 944 are formed on two different surfaces of a sealing cap 962 of an OLED device 96. A display unit 95 is disposed on a bottom substrate 964. The sealing cap 962, the bottom substrate 964 or the cover lens 91 may be made of a strengthened glass structure according to the above embodiments.

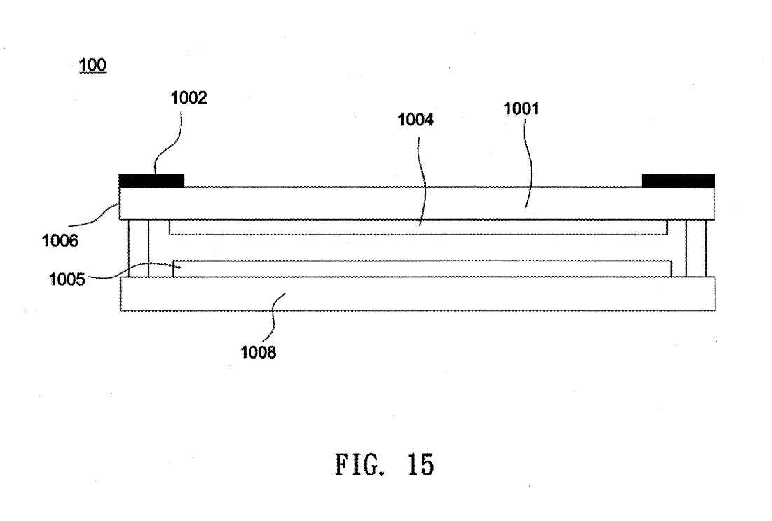

FIG. 15 shows a cross-section of a touch-sensitive display device 90 according to another embodiment of the invention. In this embodiment, a cover lens 1001 that is strengthened according to the above embodiments serves as a sealing cap of an OLED device 100, and a touch-sensing structure 1004 is formed on the strengthened cover lens 1001. An OLED unit 1005 is disposed on a bottom substrate 1008 and together with the cover lens 1001 to form a touch-sensitive display device protected by strengthened glass. Though a decorative layer 1002 shown in FIG. 15 is disposed on a top surface of the cover lens 1001, this is not limited. The decorative layer 1002 may be disposed on a bottom surface of the cover lens 1001 instead. Further, a side surface 1006 of the cover lens 1001 may be a planar surface or a curved surface, and the decorative layer 1002 may be disposed on the curved surface.

Further, the decorative layer according to the above embodiments may be disposed on a thin film to form a decoration film, and the decoration film may be attached to a top surface of a cover lens given the secondary chemically strengthening treatment to protect the cover lens, enhance the crash resistance of the cover lens, simplify the process of colorizing the decorative layer, and hence increase production yields. Besides, the touch sensing structure according to the above embodiments may be formed by a patterned transparent conductive layer, a metallic layer, a combination of a patterned transparent conductive layer and a metallic layer, or multiple metallic layers comprised of at least two different materials. The pattern of the metallic layer may be a metal mesh pattern having a trace width of 1-5 um. The metal mesh pattern may be a single layered pattern or a multi-layered pattern, where a single layered pattern may be formed by a single material (such as copper) and a multi-layered pattern may be formed by a stack of at least two metal layers (such as Mo/Al/Mo). The multi-layered pattern may be referred to as a structure where two conductive patterns are insulated from each other by a complete or a patterned dielectric layer. Certainly, the composition and material of the stacked layers are not limited to the above examples. Note the aforementioned concepts may be applied to all embodiments of the invention.

The foregoing description of the preferred embodiments of the invention has been presented for purposes of illustration and description. It is not intended to be exhaustive or to limit the invention to the precise form or to exemplary embodiments disclosed. Accordingly, the foregoing description should be regarded as illustrative rather than restrictive. Obviously, many modifications and variations will be apparent to practitioners skilled in this art. The embodiments are chosen and described in order to best explain the principles of the invention and its best mode practical application, thereby to enable persons skilled in the art to understand the invention for various embodiments and with various modifications as are suited to the particular use or implementation contemplated. It is intended that the scope of the invention be defined by the claims appended hereto and their equivalents in which all terms are meant in their broadest reasonable sense unless otherwise indicated. Therefore, the term “the invention”, “the present invention” or the like does not necessarily limit the claim scope to a specific embodiment, and the reference to particularly preferred exemplary embodiments of the invention does not imply a limitation on the invention, and no such limitation is to be inferred. The invention is limited only by the spirit and scope of the appended claims. The abstract of the disclosure is provided to comply with the rules requiring an abstract, which will allow a searcher to quickly ascertain the subject matter of the technical disclosure of any patent issued from this disclosure. It is submitted with the understanding that it will not be used to interpret or limit the scope or meaning of the claims. Any advantages and benefits described may not apply to all embodiments of the invention. It should be appreciated that variations may be made in the embodiments described by persons skilled in the art without departing from the scope of the invention as defined by the following claims. Moreover, no element and component in the present disclosure is intended to be dedicated to the public regardless of whether the element or component is explicitly recited in the following claims. Each of the terms “first” and “second” is only a nomenclature used to modify its corresponding element. These terms are not used to set up the upper limit or lower limit of the number of elements.

What is claimed is:

1. A strengthened glass block cut from a mother glass substrate given a preliminary chemically strengthening treatment, the strengthened glass block having a preliminary strengthened surface area and a newly-born surface area, and the newly-born surface area being formed as a result of a machining or material removing treatment, wherein a chemically strengthened layer formed as a result of a secondary chemically strengthening treatment is formed in at least the newly-born surface area.

2. The strengthened glass block as claimed in claim 1, wherein the preliminary strengthened surface area is larger than the newly-born surface area.

3. The strengthened glass block as claimed in claim 1, wherein the machining or material removing treatment comprises at least one of cutting, edging, drilling, chamfering, and polishing.

4. The strengthened glass block as claimed in claim 3, wherein a plurality of etched notch structures having an arc-shaped or a tooth-shaped profile are formed in the newly-born surface area.

5. The strengthened glass block as claimed in claim 1, wherein a chemically strengthened layer is formed as a result of the preliminary chemically strengthening treatment and exists only in the preliminary strengthened surface area.

6. The strengthened glass block as claimed in claim 1, further comprising:
a shielding layer formed in at least part of the preliminary strengthened surface area.

7. The strengthened glass block as claimed in claim 1, wherein the chemically strengthened layer formed as a result of the secondary chemically strengthening treatment is further disposed on at least part of the preliminary strengthened surface area.

8. The strengthened glass block as claimed in claim 1, further comprising:
a touch-sensing structure formed on a surface of the strengthened glass block.

9. The strengthened glass block as claimed in claim 8, wherein the touch-sensing structure comprises a metal mesh pattern and a trace width of the metal mesh pattern is 1-5 um.

10. The strengthened glass block as claimed in claim 1, wherein the strengthened glass block is a substrate of a display panel, or the strengthened glass block is a substrate or a cover lens of a touch panel.

11. The strengthened glass block as claimed in claim 1, wherein the strengthened glass block is a cover lens and combines with a touch panel or a display device having touch-sensing functions to form a touch-sensitive device protected by strengthened glass.

12. The strengthened glass block as claimed in claim 1, further comprising:
a decorative layer formed on the preliminary strengthened surface area, wherein the decorative layer comprises at least one of diamond-like carbon, ceramic, colored ink, resin and photo resist.

13. The strengthened glass block as claimed in claim 1, further comprising:
at least one display unit formed on a surface of the strengthened glass block.

14. The strengthened glass block as claimed in claim 1, wherein a mother glass substrate process is performed on the mother glass substrate after the preliminary chemically strengthening treatment and before the secondary chemically strengthening treatment is given to the mother glass substrate, and the mother glass substrate process comprises at least one of film deposition, photolithography, etching, screen printing and ink printing.

15. The strengthened glass block as claimed in claim 14, wherein the mother glass substrate process comprises a step of forming at least one of a touch-sensing structure and a display unit on the mother glass substrate.

16. The strengthened glass block as claimed in claim 15, wherein the step of forming the touch-sensing structure comprising patterning at least a metallic layer to form a metal mesh pattern having a trace width of 1-5 um.

17. The strengthened glass block as claimed in claim 14, wherein the mother glass substrate process comprises a step of etching a periphery of the strengthened glass block to eliminate peripheral cracks formed as a result of the machining or material removing treatment.

18. A strengthened glass block cut from a mother glass substrate given a preliminary chemically strengthening treatment, a machining or material removing treatment and a secondary chemically strengthening treatment, the strengthened glass block having a preliminary strengthened surface area and a newly-born surface area, the newly-born surface area being formed as a result of the machining or material removing treatment, and the strengthened glass block satisfying the following condition:
(d/T)≦70%,
where d is an average depth of a strengthened layer existing in the newly-born surface area and T is an average depth of a strengthened layer existing in the preliminary strengthened surface area.

19. The strengthened glass block as claimed in claim 18, wherein the strengthened layer existing in at least part of the preliminary strengthened surface area is formed as a result of the preliminary chemically strengthening treatment and the second chemically strengthening treatment, and the chemically strengthened layer existing in the newly-born surface area is formed as a result of only the secondary chemically strengthening treatment.

20. The strengthened glass block as claimed in claim 18, wherein each of the average depth of the strengthened layer existing in the newly-born surface area and the average depth of the strengthened layer existing in the preliminary strengthened surface area is defined by an average value of maximum diffusion depths of ions diffusing to the inside of the strengthened glass block.

21. The strengthened glass block as claimed in claim 18, further comprising:
a shielding layer formed on at least part of the preliminary strengthened surface area, wherein the shielding layer has at least one function of anti-scratch, anti-flare and anti-reflection.

22. The strengthened glass block as claimed in claim 18, wherein the strengthened glass block has a plurality of cut facets, and at least one of the cut facets is given the machining or material removing treatment to form a curved surface.

23. The strengthened glass block as claimed in claim 18, wherein the strengthened glass block is a cover lens and further comprises:
a decorative layer formed in at least part of a periphery of the cover lens; and
a capacitive-type touch-sensing structure formed on the cover lens, wherein the capacitive-type touch-sensing structure and the decorative layer are formed on the same side of the cover lens.

24. The strengthened glass block as claimed in claim 18, further comprising:
a display unit formed on a surface of the strengthened glass block.

25. A touch-sensitive display device protected by strengthened glass, comprising:
a cover lens cut from a mother glass substrate given a preliminary chemically strengthening treatment, the cover lens having a preliminary strengthened surface area and a newly-born surface area, and the newly-born surface area being formed as a result of a machining or material removing treatment, wherein a chemically strengthened layer formed as a result of a secondary chemically strengthening treatment is formed in at least the newly-born surface area; and
a display device with touch-sensing functions disposed on the cover lens.

26. The touch-sensitive display device as claimed in claim 25, wherein the display device with touch-sensing functions comprises:
a flat panel display; and
a touch panel disposed between the cover lens and the flat panel display.

27. The touch-sensitive display device as claimed in claim 25, wherein the cover lens has a first touch-sensing structure, and the display device with touch-sensing functions has a second touch-sensing structure.

28. The touch-sensitive display device as claimed in claim 27, wherein the display device with touch-sensing functions comprises:
a first substrate having a thin film transistor array; and
a second substrate disposed between the first substrate and the cover lens, wherein the second substrate has the second touch-sensing structure.

29. An OLED display device, comprising:
a cover lens cut from a mother glass substrate given a preliminary chemically strengthening treatment, the cover lens having a preliminary strengthened surface area and a newly-born surface area, and the newly-born surface area being formed as a result of a machining or material removing treatment, wherein a chemically strengthened layer formed as a result of a secondary chemically strengthening treatment is formed in at least the newly-born surface area;
a touch-sensing structure disposed on the cover lens; and
a substrate disposed adjacent to the cover lens and having an OLED unit.
